(19) United States
(12) Patent Application Publication
(10) Pub. No.: US 2005/0067689 A1
(43) Pub. Date: Mar. 31, 2005

(54) Semiconductor module and method for producing a semiconductor module

(76) Inventors: Harry Hedler, Germering (DE); Roland Irsigler, Munchen (DE); Thorsten Meyer, Erlangen (DE)

Correspondence Address: JENKINS & WILSON, PA, 3100 TOWER BLVD, SUITE 1400, DURHAM, NC, 27707, US

(21) Appl. No.: 10/900,578

(22) Filed: Jul. 28, 2004

(30) Foreign Application Priority Data
Sep. 30, 2003 (DE) 10345377.6

(51) Int. Cl. G03F 3/08

(52) U.S. Cl. 257/706

(57) ABSTRACT

The present invention provides a semiconductor module having: at least one semiconductor device (10); a rigid covering device (14) over the at least one semiconductor device (10) for protecting and dissipating heat from the at least one semiconductor device (10); and a carrier device (17), which has a connection device (19), for receiving the semiconductor device (10) and the covering device (14), the at least one semiconductor device (10) being electrically coupled to the connection device (19) by means of a flexible contact device (11) via the carrier device (17) and being mechanically coupled to the covering device (14) via a contact device (15, 16). The present invention likewise provides a method for producing a semiconductor module.

The present invention relates to a semiconductor module and a method for producing a semiconductor module, and in particular to a flip-chip arrangement in a package without a so-called underfill.

The use of higher clock frequencies and thus the increase in the performance of semiconductor devices, in particular memory chips, require the housing technology to be adapted. The functionality and reliability of a semiconductor chip may be restricted or no longer ensured as a result of parasitic effects attributed to the housing. It is necessary, principally in the case of high frequencies occurring, to minimize the parasitic variables, such as the nonreactive resistance, capacitive reactance and inductive reactance (R, 1/ωC, ωL), by structural measures in a housing or package construction.

In known flip-chip in package arrangements, by way of example, bonding wires are replaced by flip-chip connections and leadframes by flexible or rigid substrates. What is problematic in this case is that mechanical strains occur during temperature alternation cycles on account of the different coefficients of thermal expansion (CTE) of a semiconductor device of e.g. approximately 3 ppm/K and of a substrate of approximately 18 ppm/K. These may lead to fracture and thus interruption of the electrical connections between a semiconductor device, such as a chip, and a substrate.

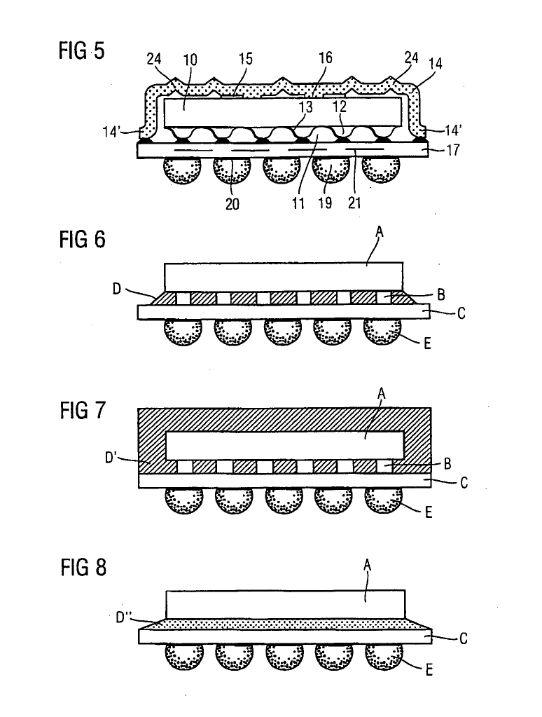

Generally, therefore, such flip-chip configurations in a package are underfilled in accordance with FIG. 6 and FIG. 8 or completely encapsulated or overmolded in an injection molding step in accordance with FIG. 7. As a result, the chip A is connected to the substrate C, which are electrically contact-connected via solder balls B, so fixedly that chip A and substrate C expand and contract uniformly during a temperature alternation cycle. However, this leads to a slight flexure of the entire package. The sheeting of the chip A with the molding compound D in accordance with FIG. 7 simultaneously serves for mechanical protection. For the flip-chip connections, in addition to the solder balls B in accordance with FIG. 6 and FIG. 7, other contact elements are also used, such as, for example, gold stud bumps, nickel bumps, or the like. The contact elements are electrically conductively connected to the substrate C by means of solder B, conductive adhesive, by compression, or similar methods, in the flip-chip production process.

The contact elements B have only very limited flexibility with regard to compensating for thermal strains on account of the different coefficients of thermal expansion between chip A and substrate C in the event of a temperature change. Therefore, the connection between chip A and substrate C is stiffened by introduction of an underfill material D, D′, D″ in an underfill process. In this case, the underfill process is effected either subsequently (capillary flow underfill D in accordance with FIG. 7, underfill molding D′ in accordance with FIG. 7) or as early as during the flip-chip mounting (e.g. no flow underfill, anisotropic conductive adhesive D″ in accordance with FIG. 8). It is likewise known to use covers for better heat dissipation (heat spreader) in the case of underfilled flip-chip configurations.

The known arrangements mentioned above have the disadvantage that a warpage or a distortion of the entire package occurs, principally in the case of relatively large semiconductor chips, on account of the different coefficients of thermal expansion between chip A, substrate C and molding compound D, D′, D″. This may adversely affect the package test and the packaging mounting. Moreover, the warpage of the package may give rise to a delamination of the molding compound D from the substrate C or from the chip A. What is more, molding compounds D, D′ exhibiting poor thermal conductivity may generally impede the dissipation of heat to the substrate C or the emission of heat to the surroundings.

Therefore, it is an object of the present invention to provide a semiconductor module and a method for producing a semiconductor module by means of which it is possible to produce robust and reliable semiconductor modules whilst avoiding an underfill or molding process, and to avoid the occurrence of thermal stresses between a semiconductor device and a carrier substrate, an electrical linking being provided between the semiconductor device and the carrier substrate.

According to the invention, this object is achieved by means of the semiconductor module specified in claim 1 and by means of the method for producing a semiconductor module according to claim 12.

The idea on which the present invention is based essentially consists in a semiconductor device being electrically contact-connected to a carrier device via flexible contact devices, the semiconductor device being protected by a covering device.

In the present invention, the problem mentioned in the introduction is solved in particular by virtue of the fact that a semiconductor module is provided having: at least one semiconductor device; a rigid covering device over the at least one semiconductor device for protecting and dissipating heat from the at least one semiconductor device; and a carrier device, which has a connection device, for receiving the semiconductor device and the covering device, the at least one semiconductor device being electrically coupled to the connection device by means of a flexible contact device via the carrier device and being mechanically coupled to the covering device via a contact device.

Such a configuration has the advantage that the semiconductor device and the carrier device and/or preferably the semiconductor device and the covering device are connected to one another via a flexible material. As a result, thermal strains cannot occur. At the same time, however, the robustness of the semiconductor module, i.e. of the package, is ensured by the fixedly mounted covering device. Warpage of the semiconductor module cannot therefore occur. The configuration according to the invention is suitable in particular for large semiconductor devices or chips with a large distance from the chip center. The covering device is preferably composed of a material exhibiting good thermal conductivity, such as e.g. a metal, thereby improving the heat dissipation.

Furthermore, such a metal cover may simultaneously be used for electrical streaming of electromagnetic interference fields. Complete soldering or adhesive bonding of the edge of the covering device affords the possibility of providing a hermetic screening from the surroundings, in particular against ambient influences, such as e.g. air humidity. What is additionally advantageous is the fact that semiconductor devices with flexible contact elements can be tested with less complexity at the wafer level than semiconductor devices with rigid contact elements (wafer level test). Apart from this, such a configuration without underfill material affords the possibility of a “rework” i.e. a decomposition of the arrangement for repair purposes in the event of a fault.

Advantageous developments and refinements of the semiconductor module according to the invention and of the method according to the invention for producing a semiconductor module are found in the subclaims.

In accordance with one preferred development, in that the flexible contact device has elastically deformable contact elevations, preferably made of a polymer, such as e.g. silicone, in particular made of a conductive adhesive.

In accordance with a further preferred development, in that the flexible contact device has metallic spring elements.

In accordance with a further preferred development, in that the rigid covering device has a coefficient of thermal expansion identical or similar to that of the carrier device.

In accordance with a further preferred development, in that the rigid covering device is formed in well-shaped fashion and is preferably composed of a metal.

In accordance with a further preferred development, in that the rigid covering device is adhesively bonded or soldered onto the carrier device, preferably with hermetic sealing.

In accordance with a further preferred development, in that a multiplicity of semiconductor devices are provided in the module.

In accordance with a further preferred development, in that the at least one semiconductor device has a memory device.

In accordance with a further preferred development, in that the covering device is adhesively bonded to the semiconductor device by means of an adhesive, which preferably has a low modulus of elasticity, at least in a predetermined section.

In accordance with a further preferred development, in that the electric contact-connection between the flexible contact device of the at least one semiconductor device and the connection device of the carrier device is provided by means of solder or conductive adhesive.

In accordance with a further preferred development, in that the covering device has, at least on its outer side, projections and/or depressions for the purpose of enlarging the surface area.

In accordance with a further preferred development, in that the flexible contact device is produced by imprinting at least one flexible elevation and preferably applying and patterning a rewiring device on the at least one semiconductor device and in particular on the at least one flexible elevation.

In accordance with a further preferred development, as the connection device, solder balls are applied to the carrier device.

Exemplary embodiments of the invention are illustrated in the drawings and are explained in more detail in the description below.

In the figures:

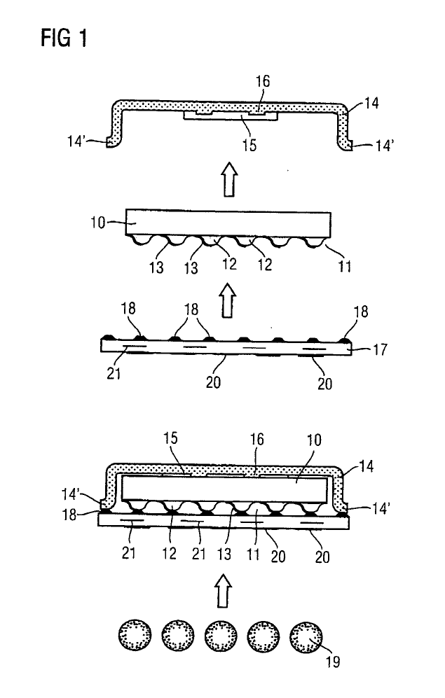

FIG. 1 shows a diagrammatic cross-sectional view of a mounting sequence for a semiconductor module for elucidating a first embodiment of the present invention,

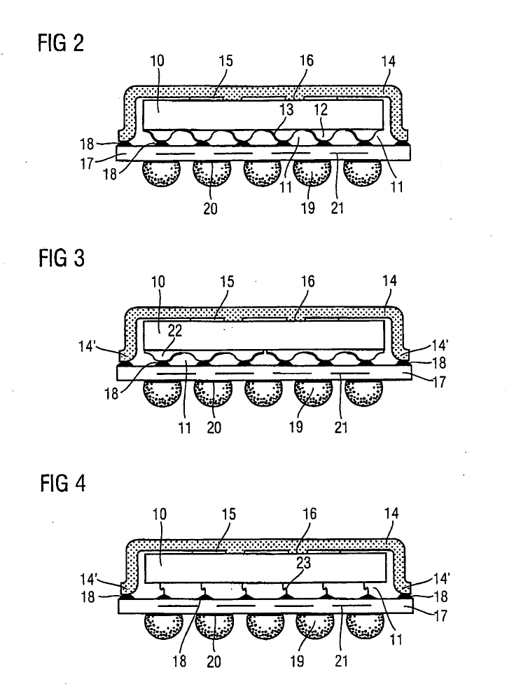

FIG. 2 shows a diagrammatic cross-sectional view of a semiconductor module for elucidating the first embodiment of the present invention;

FIG. 3 shows a diagrammatic cross-sectional view of a semiconductor module for elucidating a second embodiment of the present invention;

FIG. 4 shows a diagrammatic cross-sectional view of a semiconductor module for elucidating a third embodiment of the present invention;

FIG. 5 shows a diagrammatic cross-sectional view of a semiconductor module for elucidating a fourth embodiment of the present invention; and

FIGS. 6 to 8 in each case show a diagrammatic cross-sectional view of a known semiconductor module.

In the figures, identical reference symbols designate identical or functionally identical constituent parts.

FIG. 1 illustrates a kind of exploded cross-sectional illustration of a semiconductor device 10, preferably a semiconductor memory, during mounting to form a semiconductor module. In accordance with the preferred embodiment in FIG. 1, the semiconductor device 10 has a flexible contact device 11 in the form of elastically deformable contact elevations 12 preferably with a rewiring device 13 running in sections on the flexible contact elevations 12. The rewiring device 13 is electrically conductively connected to the semiconductor device 10. In accordance with the exemplary embodiment, it is applied, and patterned, after the application of the elastically deformable contact elevations 12 to the semiconductor device 10 and preferably to the elastically deformable contact elevations 12.

The elastically deformable contact elevations 12 comprise a polymer such as silicone, for example, and may be embodied both in conductive fashion and in nonconductive fashion. If the contact elevations 12 are produced from a nonconductive material, then a rewiring device 13 extending onto the flexible contact elevations 12 is necessary. In the case of flexible contact elevations 12 made of a conductive material, such as conductive adhesive, for example, it is necessary merely for the conductive contact elevations 12 to be electrically contact-connected to the semiconductor device 10, for example via a rewiring device 13.

In accordance with the exemplary embodiment in FIG. 1, the semiconductor device 10 is introduced into a covering device 14 by the side that is remote from the contact device 11. The covering device 14 has an essentially U-shaped or well-shaped profile in cross section and is preferably composed of a material exhibiting good thermal conductivity, such as e.g. a metal, for the purpose of better dissipating heat from the semiconductor device 10 during operation.

The semiconductor device 10 is preferably adhesively bonded in a predetermined section e.g. centrally by means of an elastic adhesive 15. In order to maintain distance between the covering device 14 and the semiconductor device 10, two spaces 16 in the form of shaped projections are preferably provided on the covering device 14. If the semiconductor device 10 is introduced into the covering device 14 and butts against the spacers 16 of the covering device 14, then the semiconductor device 10 including the contact device 11 extends in the vertical direction approximately as far as or somewhat further than the edge 14′ of the covering device 14. A soldering resist layer (not illustrated) is preferably provided in predetermined sections around the flexible contact elevations 12 on the semiconductor device 10.

A carrier device 17 or a carrier substrate is thereupon electrically connected to the contact device 11 of the semiconductor device 10 preferably via solder pads or conductive adhesives 18 in a flip-chip process. Preferably simultaneously, the edge 14′ of the covering device 14 is in this case soldered or adhesively bonded in sections or completely on the carrier device 17. The material of the covering device 14 preferably has a coefficient of thermal expansion (CTE) the same as or similar to that of the carrier device 17. The adhesive 15 is preferably so soft, i.e. has a low modulus of elasticity, such as e.g. silicon, that thermal stresses between the semiconductor device 10 and the carrier device 17 can be compensated for by the adhesive 15. The same applies to the flexible contact device 11.

This is followed by the application of a connection device 19 to that side of the carrier device 17 which is remote from the semiconductor device 10. The connection device 19 preferably has solder balls provided on contact pads 20 of the carrier device. The contact pads 20 of the carrier device 17 are electrically connected to the contact device 11 of the semiconductor device 10. Preferably, the carrier device 21 has inner layers (rewiring layers, power or GND layers).

A semiconductor module assembled in accordance with FIG. 1 is illustrated in cross section in FIG. 2. Although a flexible adhesive 15 is provided between the covering device 14 and the semiconductor device 10 in accordance with FIG. 1 and FIG. 2, it is possible also to omit this adhesive 15, i.e. the covering device 14 is then contact-connected to the semiconductor device 10 merely via the spaces 16, preferably under slight pressure, in order to ensure an even higher mobility when undergoing temperature cycles between the covering device 14 and the semiconductor device 10.

FIG. 3 diagrammatically illustrates in cross section a semiconductor module which differs from that explained with reference to FIG. 1 and FIG. 2 essentially in that individual elastically deformable contact elevations in accordance with FIG. 1 and FIG. 2 are not provided as contact device 11 on the semiconductor device 10, but rather a flexible layer 22 provided with a patterned rewiring device 13 as electrical connection between the semiconductor device 10 and the carrier device 17. The flexible layer 22 is preferably composed of an elastically deformable polymer, such as silicone, for example.

FIG. 4 differs from the embodiment in accordance with FIG. 1 and FIG. 2 essentially by the use of conductive spring elements 23 as contact device 11 for electrically contact-connecting the semiconductor device 10 to the connection device 19.

The arrangement illustrated in FIG. 5 differs from the configuration in accordance with FIG. 1 and FIG. 2 essentially in the form of the covering device 14, which is provided with shaped parts 24 in order to enlarge the surface area and thus in order to improve the dissipation of heat from the semiconductor device 10.

Although the present invention has been described above on the basis of preferred exemplary embodiments, it is not restricted thereto, but rather can be modified in diverse ways. Thus, further cover-like forms with corresponding surface structures, such as e.g. cooling fins or the like, are possible besides the illustrated variants of the covering device 14. The dimensioning and also the material examples of the covering device can also be extended. The adhesive 15 between covering device 14 and semiconductor device 10, if present, may be composed of a flexible material exhibiting good thermal conductivity in order to further optimize the dissipation of heat from the semiconductor device 10.

Principally, the flexible contact device 11 can be generated in diverse ways, such as, for example, by means of polymer bumps, polymer areas, spring elements, such as microsprings or nanosprings, or else arbitrary combinations thereof. The contact device 11 is also not restricted to being electrically conductively connected to the carrier device 17 by solder or conductive adhesive. The electrical contact between the contact device 11 and the carrier device 17 may also be effected by simply pressing the flexible contact device 11 onto the carrier device 17. What is more, the number of semiconductor devices 10 under a covering device is variable, which may be arranged one beside the other and/or one above the other and, in particular, have different chip sizes. The relative sizes and material thicknesses illustrated in the figures are to be regarded merely by way of example.

### List of reference symbols

10 semiconductor device preferably memory
11 flexible contact device
12 elastically deformable contact elevation
13 rewiring device, e.g. on contact elevation
14 covering device, preferably metal cover
14′ edge of the covering device
15 elastic adhesive
16 spacer
17 carrier device
18 solder/conductive adhesive pad
19 connection device, preferably solder balls
20 contact pads of the carrier device
21 screening device
22 flexible layer with contact elements
23 conductive spring elements
24 shaped part
A semiconductor chip
B solder wall, in particular interconnect chip/substrate
C substrate
D capillary flow underfill
D′ molded underfill
D″ anisotropic conductive adhesive
E solder ball

1. Semiconductor module having:
(a) at least one semiconductor device;
(b a rigid covering device over the at least one semiconductor device for protecting and dissipating heat from the at least one semiconductor device; and
(c) carrier device, which has a connection device, for receiving the semiconductor device and the covering device, the at least one semiconductor device being electrically coupled to the connection device by means of a flexible contact device via the carrier device and being mechanically coupled to the covering device via a contact device.

2. Semiconductor module according to claim 1, wherein the flexible contact device has elastically deformable contact elevations, preferably made of a polymer, such as e.g. silicone, in particular made of a conductive adhesive.

3. Semiconductor module according to claim 1, wherein the flexible contact device has metallic spring elements.

4. Semiconductor module according to claim 1, wherein the rigid covering device has a coefficient of thermal expansion identical or similar to that of the carrier device.

5. Semiconductor module according to claim 1, wherein the rigid covering device is formed in well-shaped fashion and is preferably composed of a metal.

6. Semiconductor module according to claim 1, wherein the rigid covering device is adhesively bonded or soldered onto the carrier device, preferably with hermetic sealing.

7. Semiconductor module according to claim 1, wherein a multiplicity of semiconductor devices are provided in the module.

8. Semiconductor module according to claim 1, wherein the at least one semiconductor device has a memory device.

9. Semiconductor module according to claim 1, wherein the covering device is adhesively bonded to the semiconductor device by means of an adhesive, which preferably has a low modulus of elasticity, at least in a predetermined section.

10. Semiconductor module according to claim 1, wherein the electric contact-connection between the flexible contact device of the at least one semiconductor device and the connection device of the carrier device is provided by means of solder or conductive adhesive or by simple pressing-on.

11. Semiconductor module according to claim 1, wherein the covering device has, at least on its outer side, projections and/or depressions for the purpose of enlarging the surface area.

12. Method for producing a semiconductor module having the following steps:
(a) applying of a flexible contact device to at least one semiconductor device;
(b) receiving of the at least one semiconductor device in a rigid covering device for protecting and dissipating heat from the at least one semiconductor device;
c) applying of the at least one semiconductor device to a carrier device;
d) fitting of the covering device to the carrier device; and
e) fitting of a connection device to the carrier device, the at least one semiconductor device being electrically coupled to the connection device by means of the flexible contact device and via the carrier device.

13. Method according to claim 12, wherein steps (c) and (d) are effected simultaneously and the at least one semiconductor device is electrically contact-connected to the carrier device.

14. Method according to claim 12, wherein the flexible contact device is produced by imprinting at least one flexible elevation and preferably applying and patterning a rewiring device on the at least one semiconductor device and in particular on the at least one flexible elevation.

15. Method according to claim 12, wherein the covering device is adhesively bonded to the semiconductor device at least in sections, preferably by means of a flexible adhesive.

16. Method according to claim 12, wherein as the connection device, solder balls are applied to contact pads the carrier device.
